(19) United States
(12) Patent Application Publication
(10) Pub. No.: US 2024/0332904 A1
(43) Pub. Date: Oct. 3, 2024

(54) SEMICONDUCTOR COMPONENT

(71) Applicant: TRUMPF Photonic Components GmbH, Ulm (DE)

(72) Inventors: Stephan Gronenborn, Aachen (DE); Johanna Sophie Kolb, Aachen (DE)

(21) Appl. No.: 18/661,788

(22) Filed: May 13, 2024

Related U.S. Application Data
(63) Continuation of application No. PCT/EP2022/080194, filed on Oct. 28, 2022.

(30) Foreign Application Priority Data
Nov. 16, 2021 (DE) 10 2021 129 874.1

(51) Int. Cl. H01S 5/183

(52) U.S. Cl. CPC H01S 5/18347; H01S 5/18327

(57) ABSTRACT

A semiconductor component for emitting light, having a base body that has at least one mesa body with an emission region for light, the at least one mesa body being arranged on a surface of the base body and is assigned a first mirror portion, a second mirror portion, and an active layer arranged between the two mirror portions for generating the light, and having a contact unit for feeding electrical energy into the active layer, the contact unit having a joining portion for joining and/or for external contacting of the semiconductor component and an active contact portion that is arranged between the joining portion and the active layer, the at least one contact unit being arranged on a side of the base body opposite to the emission region, the joining portion at least partially covering the mesa-receiving body portion and a mesa-free body portion of the base body.

### CROSS REFERENCE TO RELATED APPLICATIONS

This application is a continuation of International Application No. PCT/EP2022/080194 (WO 2023/088659 A1), filed on Oct. 28, 2022, and claims benefit to German Patent Application No. DE 10 2021 129 874.1, filed on Nov. 16, 2021. The aforementioned applications are hereby incorporated by reference herein.

### FIELD

The invention relates to a semiconductor component for emitting laser light.

### SUMMARY

In an embodiment, the present disclosure provides a semiconductor component for emitting light having a base body that has at least one mesa body arranged on a mesa-receiving body portion with an emission region for the light, the at least one mesa body being arranged on a surface of the base body and which is assigned a first mirror portion, a second mirror portion, and an active layer arranged between the two mirror portions for generating the light, and at least one contact unit for feeding electrical energy into the active layer, the contact unit comprising a joining portion for joining and/or, in respect of the base body, for external contacting of the semiconductor component and an active contact portion that is arranged between the joining portion and the active layer, the at least one contact unit being arranged on a side of the base body opposite to the emission region, the joining portion at least partially covering the mesa-receiving body portion and a mesa-free body portion of the base body.

In an embodiment, the joining portion has at least one connecting element for connection by means of a soldering method to a further component, the at least one connecting element having a joining face that faces away from the surface.

In an embodiment, an array arrangement having at least two mesa bodies is formed on the base body, the mesa-free body portion being arranged directly next to the array arrangement.

In an embodiment, the mesa-free body portion is arranged on an edge of the base body and not arranged between two mesa-receiving body portions.

In an embodiment, at least one mesa body is partially covered by a connecting element.

In an embodiment, the connecting element has, parallel to a main extent plane of the base body, a contour that has straight side lines, the contour in particular approximately being a rectangle.

In an embodiment, a connecting element is arranged fully on the mesa-free body portion and/or a further connecting element is arranged fully on the mesa-receiving body portion.

In an embodiment, a connecting element covers an entirety of the mesa-receiving body portion.

In an embodiment, a separating trench that is bounded by mesa bodies and at least one supporting web integrated into the base body is formed between two directly neighboring mesa bodies.

In an embodiment, a separating trench is formed between the mesa body and the mesa-free body portion.

In an embodiment, the mesa body is enclosed by four separating trenches the four separating trenches being separated from one another by supporting webs.

In an embodiment, the separating trench is formed transversely with respect to a main crystal direction.

In an embodiment, the electrical conductivity of the supporting web is reduced, in particular by an oxidation process and/or an implantation process, in relation to the electrical conductivity of the material of the mesa bodies.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a section through a semiconductor component with a contact unit extending over a mesa-receiving body portion and over a mesa-free body portion of the semiconductor component;

FIG. 2 shows a section through a semiconductor component with a contact unit arranged on a mesa-receiving body portion of the semiconductor component and a contact unit arranged on a mesa-free body portion of the semiconductor component; and

FIG. 3 shows a plan view of an array arrangement that contains mesa bodies and on which contact units are arranged.

### DETAILED DESCRIPTION

It is proposed to provide a semiconductor component for emitting light, having a base body that has at least one mesa body arranged on a mesa-receiving body portion with an emission region for the light, which is arranged on a surface of the base body and which is assigned a first mirror portion, a second mirror portion and an active layer arranged between the two mirror portions for generating the light, and having at least one contact unit for feeding electrical energy into the active layer, the contact unit having a joining portion, which is provided for joining and/or, in respect of the base body, for external contacting of the semiconductor component, and an active contact portion which is arranged between the joining portion and the active layer, the contact unit being arranged on a side of the base body opposite to the emission region, the joining portion at least partially covering the mesa-receiving body portion and a mesa-free body portion of the base body.

The area covered by the contact unit may thereby be increased, so that the dissipation of heat from the base body is improved in relation to conventional semiconductor components. Further, the mechanical strength against defects generated by temperature variations in the semiconductor component is improved.

The mesa-receiving body portion has the mesa bodies and is configured to be less resistant to mechanical influences in comparison with the mesa-free body portion that does not have mesa bodies.

Advantageous embodiments and developments of the invention are possible by the measures specified in the dependent claims.

Preferably, the joining portion may have at least one connecting element, which is provided in particular for connection by means of a soldering method to a further component, the connecting element having a joining face that faces away from the surface.

Advantageously, an array arrangement having at least two mesa bodies may be formed on the base body, the mesa-free body portion being arranged directly next to the array arrangement.

In particular, the mesa-free body portion may be arranged on an edge of the base body, the edge being positioned on a radially outlying base body portion as seen along a main extent plane of the base body. In one particular embodiment, the mesa-free body portion is preferably not arranged between two mesa-receiving body portions.

At least one mesa body that is partially covered by the connecting element is particularly preferred. Besides this, there may be mesa bodies that are fully covered.

In particular, the individual connecting elements of an individual contact unit may fulfill the features of the embodiments described above and below.

In order to achieve an efficient and space-saving arrangement of the connecting elements on the surface of the base body, the respective connecting element may have a contour that is formed parallel to the main extent plane of the base body and has straight side lines, the contour in particular approximately being a rectangle. For example, the connecting elements may be rectangles with sides of different length or squares. The corners may be angled or may have a radius. Alternatively or in addition, the connecting elements may also have other shapes, such as honeycomb shapes or round shapes.

In addition or alternatively, a connecting element may be arranged fully on the mesa-free body portion and/or a further connecting element may be arranged fully on the mesa-receiving body portion.

In an alternative embodiment, a single connecting element may cover the entire mesa-receiving body portion and preferably at least one portion of the mesa-free body portion.

According to one advantageous development of the invention, a separating trench, which is bounded by the mesa bodies and at least one supporting web integrated into the base body, is formed between two directly neighboring mesa bodies. The supporting web supports the two neighboring mesa bodies, so that a mechanical stability of the mesa-receiving body portion is increased. Functional stack layers of various mesa bodies are electrically separated from one another by the separating trenches. In particular, the separating trenches do not separate all layers.

Further, a separating trench may be formed between a mesa body and a mesa-free body portion.

In order to achieve an improved electrical separation of a mesa body from neighboring mesa bodies in an array arrangement, it is proposed to enclose the mesa bodies by four separating trenches, which are separated from one another respectively by a supporting web. For example, the separating trenches may be arranged along the sides of an imaginary square, the side lines of which enclose the respective mesa body.

In particular, a separating trench may be formed transversely with respect to a main crystal direction. This may prevent the translation of crystal defects, for example dislocations, since the translational symmetry of the crystal lattice on which the semiconductor component is based is broken.

The electrical separation may be further improved by reducing the electrical conductivity of the supporting web, in particular by an oxidation process and/or an implantation process, in relation to the electrical conductivity of the material of the mesa body. Functional layers of the respective mesa bodies may therefore be substantially insulated by the separating trenches and the treated supporting webs.

It is to be understood that the features specified above and the features yet to be explained below may be used not only in the respectively specified combination but also in other combinations.

Each embodiment of the present invention may be configured as a so-called top emitter and/or bottom emitter.

The scope of the invention is defined only by the claims.

The invention will be explained in more detail below on the basis of the exemplary embodiments with reference to the appended drawings. Direction indications in the following explanation are to be understood according to the reading direction of the drawings.

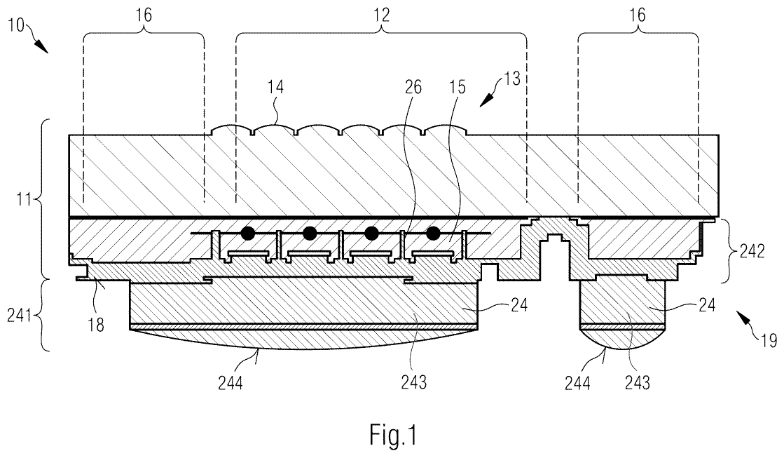

FIG. 1 shows a section through a semiconductor component 10 with a contact unit 24 extending over a mesa-receiving body portion 12 and over a mesa-free body portion 16 of the semiconductor component 10. A base body 11 of the semiconductor component 10 for emitting light has at least one mesa-receiving body portion 12 comprising a mesa body 15 with an emission region 13 for the laser light. An optical element 14 in the form of a diffractive structure, such as a grating or a refractive lens or a photonic metamaterial, may be arranged on the emission region 13. The optical element 14 may, in particular, be integrated into the structure of the base body 11.

The base body 11 has a stack of Bragg mirrors and an active portion arranged between the two Bragg mirrors for generating the laser light.

In particular, the contact unit 24 has a joining portion 241, which is provided for joining and/or, in respect of the base body 11, for external contacting of the semiconductor component 10. A further component may be brought to the joining portion 241 from the outside and connected to the contact unit 24 by means of the joining portion 241. This may be an electrically established and/or mechanical connection.

Further, the contact unit 24 has an active contact portion 242 which is arranged between the joining portion 241 and the active layer. The contact unit 24 is arranged on a side 19 of the base body 11 opposite to the emission region 13, the joining portion 241 at least partially covering the mesa-receiving body portion 12 and a mesa-free body portion 16 of the base body 11.

The joining portion 241 arranged on the base body 11 for feeding electrical energy into the active portion, which is arranged on the surface 18 on the side of the base body 11 opposite to the emission region 13, has at least one connecting element 243. The connecting element 243 is in particular provided for connection by means of a soldering method to a further component, the connecting element 243 having a joining face 244 that faces away from the surface 18. The joining face 244 may be used for soldering the further component. It may comprise a different metal than the active contact portion and/or a portion of the connecting element 243 that is arranged between the joining face 244 and the active contact portion.

According to exemplary FIG. 1, the semiconductor component 10 has at least one mesa body 15 arranged on the mesa-receiving body portion 12. The mesa-receiving base body 11 has at least two mesa bodies 15, which form an array arrangement.

The base body 11 further has a mesa-free body portion 16 of the base body 11. The mesa-free body portion 16 is arranged directly next to the array arrangement of the mesa-receiving body portion 12. In particular, the mesa-free body portion 16 may not be arranged between two mesa-receiving body portions

The mesa-receiving body portion 12 has the mesa body 15 and is configured to be less robust against mechanical influences than the mesa-free body portion 16, which does not have mesa bodies 15.

The base body 11 may be configured in the shape of a plate, the stack constituting a substantial portion of the base body 11 having its stack direction transverse with respect to the main extent plane of the plate-like base body 11. The mesa-free body portion 16 is preferably arranged on an edge of the base body 11. The edge is preferably positioned on a radially outlying base body portion as seen along the main extent plane of the base body 11. The main extent plane is preferably aligned perpendicularly with respect to the plane of the drawing of FIG. 1.

The connecting element 243 of the semiconductor component 10 of FIG. 1 preferably extends over all or at least a large part of the mesa bodies 15. At the same time, it also extends over the mesa-free body portion. The connecting element 243 also extends over a boundary region between the mesa-receiving and mesa-free body portions. A further connecting element 243 of the semiconductor component 10 of FIG. 1 is arranged only on the mesa-free body portion 16. Preferably, the connecting element 243 that at least partially covers the mesa-receiving body portion 12 is larger than the connecting element 243 that is arranged on the mesa-free body portion 16.

All connecting elements 243 are arranged on the side opposite to the emission region 13. The connecting elements 243 are suitable for an SMD soldering method. The semiconductor component 10 may be used as a so-called bottom emitter.

Particularly preferably, at least one mesa body 15 of the mesa-receiving body portion 12 is partially covered by the connecting elements 243. For example, a side-edge of the connecting element 243 may in this case bear on a portion of the base body 11 that contains a mesa body 15. Besides this, there may be mesa bodies 15 that are fully covered.

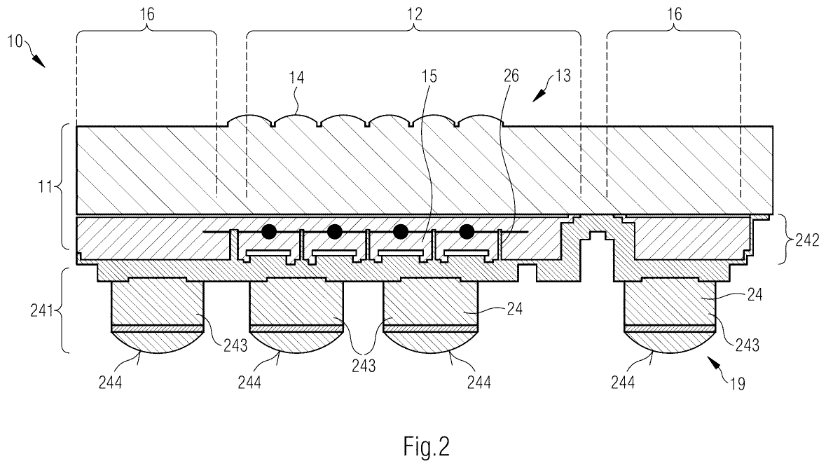

FIG. 2 represents a semiconductor component 10 in which at least one connecting element 243 is arranged fully on the mesa-free body portion 16 and/or a further connecting element 243 is arranged fully on the mesa-receiving body portion 12. The connecting elements 243 in this case do not cover the full mesa-receiving body portion 12.

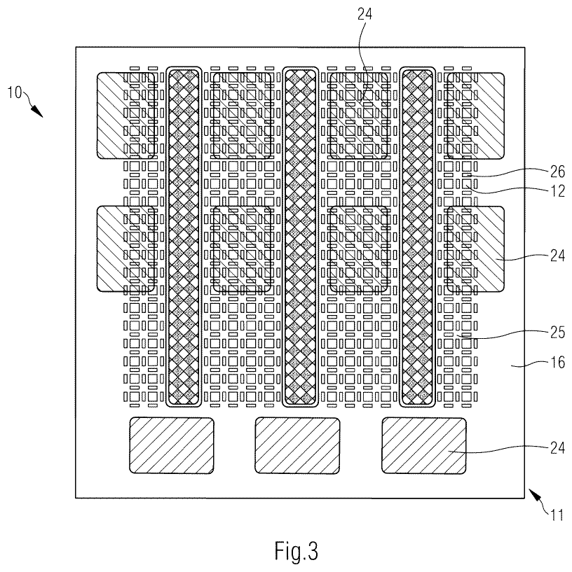

FIG. 3 represents a plan view of a semiconductor component 10 in which connecting elements 243 are arranged fully on the mesa-receiving body portion 12 and further connecting elements 243 are arranged fully on the mesa-free body portion 16, and further connecting elements 243 are arranged partially on the mesa-receiving body portion 12 and on the mesa-free body portion 16.

Parallel to the main extent plane of the base body 11, the connecting elements 243 have a contour that has straight side lines. For example, the connecting elements 243 according to FIG. 3 are rectangles with sides of different length, the corners of which have a radius. Preferably, all connecting elements 243 are shaped identically.

According to the exemplary embodiment of FIG. 3, a separating trench 26 is formed between two directly neighboring mesa bodies 15. The separating trench 26 is configured to be elongate and preferably rectilinear. The separating trench 26 generates electrical separation of one mesa body 15 from a neighboring mesa body 15.

The separating trenches may be aligned transversely with respect to main crystal directions and break a translational symmetry of the crystal lattice.

Four separating trenches 26 may be provided, which enclose the mesa body 15. For example, each individual one of the four separating trenches 26 may be arranged on a side line of an imaginary square.

Supporting webs 25, which increase the stability of the mesa-receiving body portion 12, are arranged at the longitudinal ends of the separating trenches 26. The respective supporting web is arranged between two neighboring separating trenches 26.

The electrical conductivity of the supporting webs 25 may be reduced, in particular by an oxidation process and/or an implantation process, in relation to the electrical conductivity of the material of the mesa bodies 15.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A semiconductor component for emitting light, comprising:
a base body that has at least one mesa body arranged on a mesa-receiving body portion with an emission region for the light, the at least one mesa body being arranged on a surface of the base body and which is assigned a first mirror portion, a second mirror portion, and an active layer arranged between the two mirror portions for generating the light; and
at least one contact unit for feeding electrical energy into the active layer, the contact unit comprising a joining portion for joining and/or, in respect of the base body, for external contacting of the semiconductor component and an active contact portion that is arranged between the joining portion and the active layer, the at least one contact unit being arranged on a side of the base body opposite to the emission region, the joining portion at least partially covering the mesa-receiving body portion and a mesa-free body portion of the base body.

2. The semiconductor component according to claim 1, wherein the joining portion has at least one connecting element for connection by means of a soldering method to a further component, the at least one connecting element having a joining face that faces away from the surface.

3. The semiconductor component according to claim 1, wherein an array arrangement having at least two mesa bodies is formed on the base body, the mesa-free body portion being arranged directly next to the array arrangement.

4. The semiconductor component according to claim 1, wherein the mesa-free body portion is arranged on an edge of the base body and not arranged between two mesa-receiving body portions.

5. The semiconductor component according to claim 1, wherein at least one mesa body is partially covered by a connecting element.

6. The semiconductor component according to claim 2, wherein the connecting element has, parallel to a main extent plane of the base body, a contour that has straight side lines, the contour in particular approximately being a rectangle.

7. The semiconductor component according to claim 1, wherein a connecting element is arranged fully on the mesa-free body portion and/or a further connecting element is arranged fully on the mesa-receiving body portion.

8. The semiconductor component according to claim 1, wherein a connecting element covers an entirety of the mesa-receiving body portion.

9. The semiconductor component according to claim 1, wherein a separating trench that is bounded by mesa bodies and at least one supporting web integrated into the base body is formed between two directly neighboring mesa bodies.

10. The semiconductor component according to claim 1, wherein a separating trench is formed between the mesa body and the mesa-free body portion.

11. The semiconductor component according to claim 1, wherein the mesa body is enclosed by four separating trenches the four separating trenches being separated from one another by supporting webs.

12. The semiconductor component according to claim 10, wherein the separating trench is formed transversely with respect to a main crystal direction.

13. The semiconductor component according to claim 9, wherein the electrical conductivity of the supporting web is reduced, in particular by an oxidation process and/or an implantation process, in relation to the electrical conductivity of the material of the mesa bodies.
